(19) United States
(12) Patent Application Publication
(10) Pub. No.: US 2009/0218577 A1
(43) Pub. Date: Sep. 3, 2009

(54) HIGH THROUGHPUT CRYSTALLIZATION OF THIN FILMS

(76) Inventor: James S. Im, New York, NY (US)

Correspondence Address: WilmerHale/Columbia University, 399 PARK AVENUE, NEW YORK, NY, 10022, US

(21) Appl. No.: 12/063,810

(22) PCT Filed: Aug. 16, 2006
(86) PCT No.: PCT/US06/32037

§ 371 Date: Oct. 28, 2008

Related U.S. Application Data
(60) Provisional application No. 60/708,447, filed on Aug. 16, 2005.

(51) Int. Cl. H01L 29/04; H01L 21/26; B23K 26/04; B23K 26/06; B23K 26/08

(52) U.S. Cl. 257/75; 438/795; 219/121.65; 219/121.73; 219/121.82; 257/E29.003; 257/E21.328

(57) ABSTRACT

Under one aspect, a method of processing a film includes defining a plurality of spaced-apart regions to be crystallized within a film, the film being disposed on a substrate and capable of laser-induced melting; generating a sequence of laser pulses having a fluence that is sufficient to melt the film throughout its thickness in an irradiated region, each pulse forming a line beam having a length and a width; continuously scanning the film in a first scan with a sequence of laser pulses at a velocity selected such that each pulse irradiates and melts a first portion of a corresponding spaced-apart region, wherein the first portion upon cooling forms one or more laterally grown crystals; and continuously scanning the film in a second time with a sequence of laser pulses at a velocity selected such that each pulse irradiates and melts a second portion of a corresponding spaced-apart region, wherein the first and second portions in each spaced-apart region partially overlap, and wherein the second portion upon cooling forms one or more laterally grown crystals that are extended relative to the one or more laterally grown crystals of the first portion.

### CROSS REFERENCE TO RELATED APPLICATIONS

This application claims the benefit under 35 U.S.C. §119(e) of the following application, the entire contents of which are incorporated herein by reference:
U.S. Provisional Patent Application Ser. No. 60/708,447, filed Aug. 16, 2005 and entitled “High Throughput Line-Scan SLS.”

### FIELD OF THE INVENTION

The disclosed subject matter generally relates to laser crystallization of thin films. In particular, the disclosed subject matter relates to systems and methods for high throughput crystallization of thin films.

### BACKGROUND

In recent years, various techniques for crystallizing or improving the crystallinity of an amorphous or polycrystalline semiconductor film have been investigated. Such crystallized thin films may be used in the manufacture of a variety of devices, such as image sensors and active-matrix liquid-crystal display (“AMLCD”) devices. In the latter, a regular array of thin-film transistors (“TFTs”) is fabricated on an appropriate transparent substrate, and each transistor serves as a pixel controller.

Crystalline semiconductor films, such as silicon films, have been processed to provide pixels for liquid crystal displays using various laser processes including excimer laser annealing (“ELA”) and sequential lateral solidification (“SLS”) processes. SLS is well suited to process thin films for use in AMLCD devices, as well as organic light emitting diode (“OLED”) devices.

In ELA, a region of the film is irradiated by an excimer laser to partially melt the film, which subsequently crystallizes. The process typically uses a long, narrow beam shape that is continuously advanced over the substrate surface, so that the beam can potentially irradiate the entire semiconductor thin film in a single scan across the surface. ELA produces small-grained polycrystalline films; however, the method often suffers from microstructural non-uniformities, which can be caused by pulse to pulse energy density fluctuations and/or non-uniform beam intensity profiles. FIG. 1A illustrates a random microstructure that may be obtained with ELA. The Si film is irradiated multiple times to create the random polycrystalline film with a uniform grain size. This figure, and all subsequent figures, are not drawn to scale, and are intended to be illustrative in nature.

SLS is a pulsed-laser crystallization process that can produce high quality polycrystalline films having large and uniform grains on substrates, including substrates that are intolerant to heat such as glass and plastics. Exemplary SLS processes and systems are described in commonly-owned U.S. Pat. Nos. 6,322,625, 6,368,945, 6,555,449, and 6,573,531, the entire contents of which are incorporated herein by reference.

SLS uses controlled laser pulses to melt a region of an amorphous or polycrystalline thin film on a substrate. The melted regions of film then laterally crystallize into a directionally solidified lateral columnar microstructure or a plurality of location-controlled large single crystal regions. Generally, the melt/crystallization process is sequentially repeated over the surface of a large thin film, with a large number of laser pulses. The processed film on substrate is then used to produce one large display, or even divided to produce multiple displays. FIGS. 1B-1D shows schematic drawings of TFTs fabricated within films having different microstructures that can be obtained with SLS.

When a polycrystalline material is used to fabricate devices having TFTs, the total resistance to carrier transport within the TFT channel is affected by the combination of barriers that a carrier has to cross as it travels under the influence of a given potential. Within a material processed by SLS, a carrier crosses many more grain boundaries if it travels perpendicularly to the long grain axes of the polycrystalline material, and thus experiences a higher resistance, than if it travels parallel to the long grain axes. Thus, in general, the performance of TFT devices fabricated on SLS-processed polycrystalline films depends on the microstructure of the film in the channel, relative to the film's long grain axes.

However, conventional ELA and SLS techniques are limited by variation in the laser pulses from one shot to the next. Each laser pulse used to melt a region of film typically has a different energy fluence than other laser pulses used to melt other regions of film. In turn, this can cause slightly different performance in the regions of recrystallized film across the area of the display. For example, during the sequential irradiation of neighboring regions of the thin film, a first region is irradiated by a first laser pulse having a first energy fluence; a second region is irradiated by a second laser pulse having a second fluence which is at least slightly different from that of the first laser pulse; and a third region is irradiated by a third laser pulse having a third fluence that is at least slightly different from that of the first and second laser pulses. The resulting energy densities of the irradiated and crystallized first, second and third regions of the semiconductor film are all, at least to some extent, different from one another due to the varying fluences of the sequential beam pulses irradiating neighboring regions

Variations in the fluence and/or energy density of the laser pulses, which melt regions of film, can cause variations in the quality and performance of the crystallized regions. When TFT devices are subsequently fabricated in such areas that have been irradiated and crystallized by laser beam pulses of different energy fluences and/or energy densities, performance differences may be detected. This may manifest itself in that the same colors provided on neighboring pixels of the display may appear different from one another. Another consequence of non-uniform irradiation of neighboring regions of the thin film is that a transition between pixels in one of these regions to pixels in the next consecutive region may be visible in the display produced from the film. This is due to the energy densities being different from one another in the two neighboring regions so that the transition between the regions at their borders has a contrast from one to the other. Thus crystal quality and consistency across the thin film is desirable in SLS processing.

The potential success of SLS systems and methods for commercial use is related to the throughput with which the desired microstructure can be produced. The amount of energy and time it takes to produce a film having the microstructure is also related to the cost of producing that film; in general, the faster and more efficiently the film can be produced, the more films can be produced in a given period of time, enabling higher production and thus higher potential revenues.

### SUMMARY

The application describes systems and methods for the high throughput directional or uniform, e.g., “2-shot,” crystallization of thin films.

Under one aspect, a method of processing a film includes defining a plurality of spaced-apart regions to be crystallized within a film, the film being disposed on a substrate and capable of laser-induced melting; generating a sequence of laser pulses having a fluence that is sufficient to melt the film throughout its thickness in an irradiated region, each pulse forming a line beam having a length and a width; continuously scanning the film in a first scan with a sequence of laser pulses at a velocity selected such that each pulse irradiates and melts a first portion of a corresponding spaced-apart region, wherein the first portion upon cooling forms one or more laterally grown crystals; and continuously scanning the film in a second time with a sequence of laser pulses at a velocity selected such that each pulse irradiates and melts a second portion of a corresponding spaced-apart region, wherein the first and second portions in each spaced-apart region partially overlap, and wherein the second portion upon cooling forms one or more laterally grown crystals that are extended relative to the one or more laterally grown crystals of the first portion.

One or more embodiments include one or more of the following features. Reversing the scan direction between the first and second scans. Continuously scanning the film relative to the sequence of laser pulses a plurality of times, and on each scan irradiating a portion of each spaced-apart region that partially overlaps with a previously irradiated portion of that region.

Reversing the scan direction between each scan. Fabricating at least one thin film transistor in at least one spaced-apart region. Fabricating a plurality of thin film transistors in a plurality of spaced-apart regions. Defining a plurality of spaced-apart regions includes defining a width for each spaced-apart region that is at least as large as a device intended to be later fabricated in that region. Defining a plurality of spaced-apart regions includes defining a width for each spaced-apart region that is at least as large as a width of a thin film transistor intended to be later fabricated in that region. Overlapping the first and second portions of each spaced-apart region by an amount that is less than a lateral growth length of the one or more laterally grown crystals of the first portion. Overlapping the first and second portions of each spaced-apart region by an amount that is not more than 90% of the lateral growth length of the one or more laterally grown crystals of the first portion. Overlapping the first and second portions of each spaced-apart region by an amount that is greater than a lateral growth length and less than about twice the lateral growth length of the one or more laterally grown crystals of the first portion. Overlapping the first and second portions of each spaced-apart region by an amount that is more than about 110% and less than about 190% of a lateral growth length of the one or more laterally grown crystals of the first portion. Overlapping the first and second portions of each spaced-apart region by an amount selected to provide a set of predetermined crystalline properties to the spaced-apart region. The set of predetermined crystalline properties are suitable for a channel region of a pixel TFT. The spaced-apart regions are separated by amorphous film. The spaced-apart regions are separated by polycrystalline film. The line beam has a length to width aspect ratio of at least 50. The line beam has a length to width aspect ratio of up to 2×10⁵. The length of the line beam is at least as large as one-half a length of the substrate. The length of the line beam is at least as large as a length of the substrate. The length of the line beam is between about 10 cm and 100 cm. Shaping each pulse of the sequence of pulses into a line beam using one of a mask, a slit, and a straight edge. Shaping each pulse of the sequence of pulses into a line beam using focusing optics. The fluence of the line beam varies by less than about 5% along its length. The film includes silicon.

Under another aspect, a method of processing a film includes (i) defining at least first and second regions to be crystallized within a film; (ii) generating a sequence of laser pulses having a fluence that is sufficient to melt the film throughout its thickness in an irradiated region, each pulse forming a line beam having a length and width; (iii) irradiating and melting a first portion of the first region with a first laser pulse of the sequence of pulses, the first portion of the first region upon cooling forming one or more laterally grown crystals; (iv) irradiating and melting a first portion of the second region with a second laser pulse of the sequence of pulses, the first portion of the second region upon cooling forming one or more laterally grown crystals; irradiating and melting a second portion of the second region of the plurality of regions with a third laser pulse of the sequence of pulses, the second portion of the second region overlapping with the first portion of the second region and upon cooling forming one or more laterally grown crystals; and irradiating and melting a second portion of the first region of the plurality of regions with a fourth laser pulse of the sequence of pulses, the second portion of the first region overlapping with the first portion of the first region and upon cooling forming one or more laterally grown crystals.

One or more embodiments include one or more of the following features. The one or more laterally grown crystals in the second portion of the first defined region are elongations of the one or more laterally grown crystals in the first portion of the first defined region. Fabricating at least one thin film transistor in at least one of the first and second regions. Defining a width for each of the first and second regions that is at least as large as a device intended to be later fabricated in that region. Defining a width for each of the first and second regions that is at least as large as a width of a thin film transistor intended to be later fabricated in that region. Overlapping the first and second portions of each of the first and second regions by an amount that is less than a lateral growth length of the one or more crystals of the first portions. Overlapping the first and second portions of each of the first and second regions by an amount that is not more than 90% of a lateral growth length of the one or more crystals of the first portions. Overlapping the first and second portions of each of the first and second regions by an amount that is greater than a lateral growth length and less than about twice the lateral growth length of the one or more crystals of the first portions. Overlapping the first and second portions of each of the first and second regions by an amount that is more than about 110% and less than about 190% of the lateral growth length of the one or more crystals of the first portions. Overlapping the first and second portions of each of the first and second regions by an amount selected to provide a set of predetermined crystalline properties to each of the first and second regions. The set of predetermined crystalline properties are suitable for a channel region of a pixel TFT. Executing the steps of the method in their listed order. The first and second regions are separated by uncrystallized film. The first and second regions are separated by polycrystalline film. Moving the film relative to the line beam. Scanning the film in one direction relative to the line beam while irradiating the first portions of the first and second regions, and scanning the film in an opposite direction relative to the line beam while irradiating the second portions of the first and second regions. The line beam has a length to width aspect ratio of at least 50. The line beam has a length to width aspect ratio of up to 2×10⁵. The length of the line beam is at least as large as one-half a length of the substrate. The length of the line beam is at least as large as the length of the substrate. The length of the line beam is between about 10 cm and 100 cm. Shaping each pulse of the sequence of pulses into a line beam using one of a mask, a slit, and a straight edge. Shaping each pulse of the sequence of pulses into a line beam using focusing optics. The line beam has a fluence that varies by less than about 5% along its length. The film includes silicon.

Under another aspect, a system for processing a film includes a laser source providing a sequence of laser pulses; laser optics that shape the laser beam into a line beam, the line beam having a fluence that is sufficient to melt a film throughout its thickness in an irradiated region, the line beam further having a length and a width; a stage for supporting the film and capable of translation in at least one direction; and memory for storing a set of instructions. The instructions include defining a plurality of spaced-apart regions to be crystallized within the film; continuously translating the film on the stage a first time relative to the sequence of laser pulses at a velocity selected such that each pulse irradiates and melts a first portion of a corresponding spaced-apart region, wherein the first portion upon cooling forms one or more laterally grown crystals; and continuously translating the film on the stage a second time relative to the sequence of laser pulses at a velocity selected such that each pulse irradiates and melts a second portion of a corresponding spaced-apart region, wherein the first and second portions in each spaced-apart region partially overlap, and wherein the second portion upon cooling forms one or more laterally grown crystals.

One or more embodiments include one or more of the following features. The memory further includes instructions to reverse the scan direction between the first and second scans. The memory further includes instructions to continuously translate the stage relative to the sequence of laser pulses a plurality of times, and on each scan irradiating a portion of each spaced-apart region that partially overlaps with a previously irradiated portion of that region. The memory further includes instructions to reverse the scan direction between each scan. The memory further includes instructions for defining a width for each spaced-apart region that is at least as large as a device intended to be later fabricated in that region. The memory further includes instructions for defining a width for each spaced-apart region that is at least as large as a width of a thin film transistor intended to be later fabricated in that region. The memory further includes instructions for overlapping the first and second portions of each spaced-apart region by an amount that is less than a lateral growth length of the one or more laterally grown crystals of the first portion. The memory further includes instructions for overlapping the first and second portions of each spaced-apart region by an amount that is not more than 90% of the lateral growth length of the one or more laterally grown crystals of the first portion. The memory further includes instructions for overlapping the first and second portions of each spaced-apart region by an amount that is greater than a lateral growth length and less than about twice the lateral growth length of the one or more laterally grown crystals of the first portion. The memory further includes instructions for overlapping the first and second portions of each spaced-apart region by an amount that is more than about 110% and less than about 190% of a lateral growth length of the one or more laterally grown crystals of the first portion. The memory further includes instructions for overlapping the first and second portions of each spaced-apart region by an amount selected to provide a set of predetermined crystalline properties to the spaced-apart region. The set of predetermined crystalline properties are suitable for a channel region of a pixel TFT. The laser optics shape the line beam to have a length to width aspect ratio of at least 50. The laser optics shape the line beam to have a length to width aspect ratio of up to 2×10⁵. The laser optics shape the line beam to be at least as large as one-half a length of the film. The laser optics shape the line beam to be at least as large as a length of the film. The laser optics shape the line beam to have a length between about 10 cm and 100 cm. The laser optics include at least one of a mask, a slit, and a straight edge. The laser optics include focusing optics. The laser optics shape the line beam to have a fluence that varies by less than about 5% along its length. The film includes silicon.

Under another aspect, a thin film includes columns of crystallized film positioned and sized so that rows and columns of TFTs can later be fabricated in said columns of crystallized film and having as set of predetermined crystalline qualities suitable for a channel region of a TFT; and columns of untreated film between said columns of crystallized film. In one or more embodiments, the columns of untreated film include amorphous film. In one or more embodiments, the columns of untreated film include polycrystalline film.

### BRIEF DESCRIPTION OF THE DRAWINGS

In the drawing:

FIG. 1A illustrates a TFT formed within films having crystalline microstructures formed by excimer laser annealing.

FIGS. 1B-1D illustrate TFTs formed within films having crystalline microstructures formed by sequential lateral crystallization.

FIG. 2 illustrates a thin film crystallized with high throughput crystallization according to certain embodiments.

FIG. 3 is a flow diagram of a method for the high throughput crystallization of a thin film according to certain embodiments.

FIGS. 4-6 illustrate steps in a line beam sequential lateral solidification to produce directional crystals according to certain embodiments.

FIGS. 7A-7D illustrate a line beam sequential lateral solidification process to produce uniform crystals according to certain embodiments.

FIG. 8 is a schematic diagram of an apparatus for sequential lateral crystallization of a thin film according to certain embodiments.

FIGS. 9A-9E illustrate the high throughput crystallization of a defined integration region using sequential lateral crystallization according to certain embodiments.

### DETAILED DESCRIPTION

Systems and methods described herein provide crystallized regions having improved crystal quality and consistency across the crystallized regions of the thin film, while simultaneously increasing the throughput of the crystallization process.

High throughput directional and uniform crystallization using “line-scan” sequential lateral crystallization provides efficient processing of thin films on substrates, as described in greater detail below. The thin films are directionally or uniformly crystallized only in regions of the film where devices that require highly aligned crystals, such as pixel TFTs. Regions of the film where no devices will be located or which are desirably treated using other crystallization techniques are not crystallized according to one or more embodiments. In certain embodiments, the thin film is processed in long columns using “line-scan” SLS, using an irradiation scheme that processes only those regions that need it, and in a manner that increases throughput. Note that we will refer to silicon or semiconductor films herein, but any thin film susceptible to laser-induced melt-crystallization may be so processed.

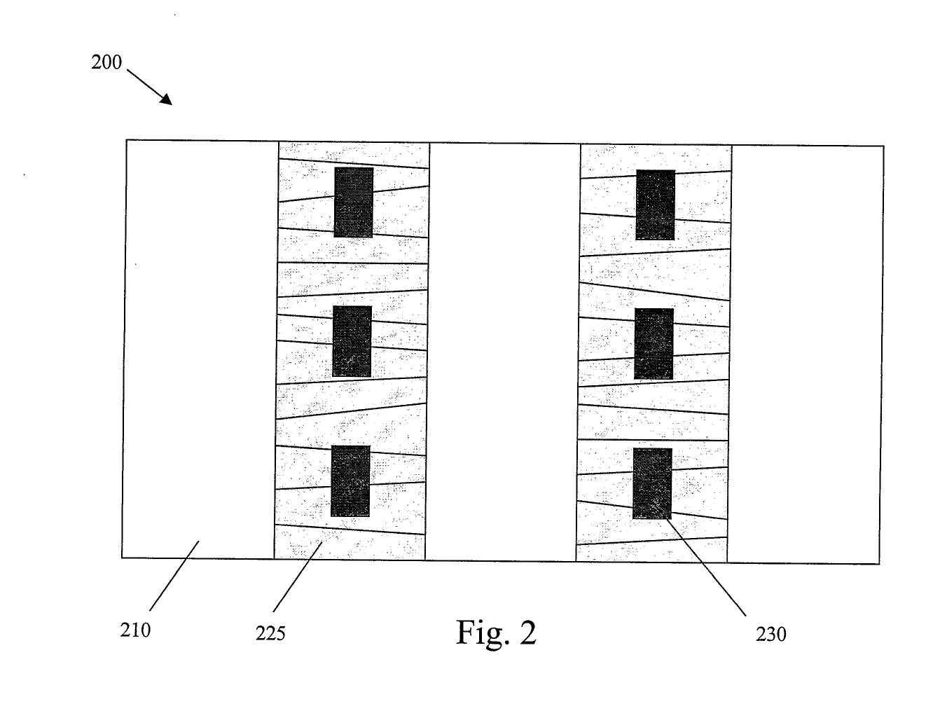

FIG. 2 illustrates a thin film 200 that has been crystallized in defined regions corresponding to TFT channels, and left untreated in other regions, according to certain embodiments. The film includes columns of crystallized silicon 225, and columns of untreated silicon 210. The columns are positioned and sized so that rows and columns of TFTs can later be fabricated within regions 230 of the columns of crystallized silicon 225. The untreated regions 210 can be uncrystallized silicon, e.g., amorphous silicon, or can be e.g., polycrystalline silicon produced in a previous processing step.

Although the columns of untreated and crystalline silicon are illustrated to have approximately the same width, the column widths and relative spacing can vary, depending on the desired density and location of TFTs in the device to be fabricated. For example, flat panel displays typically require a relatively large spacing between TFTs as compared with the size of the TFTs. In this case, the crystalline silicon columns 225 may be fabricated to be substantially narrower than the untreated columns 210. This will further improve the efficiency with which the film can be processed, because large regions of the film will not need to be crystallized. For example, a 2-inch QVGA (320×240) display has columns of TFTs that are about 20 μm wide (according to the current design rule), including the channel length and source and drain regions. The columns have a spatial periodicity of about 127 μm, so at least about 100 μm between each TFT column can be left as untreated silicon without detrimentally affecting the performance of the display. Or, for a 15-inch UXGA display (1280×960), e.g., a notebook computer display, the TFT columns may be about 30 μm wide and having a spatial periodicity of about 238 μm. Using the high-throughput line-scan SLS technique the throughput of film crystallization to be increased dramatically.

It should be noted that in the embodiment of FIG. 2, the shortest dimension of the TFT (the channel length) is optionally oriented parallel to the direction of the crystal grains. The reason for this orientation lies in the details of the microstructure: long parallel grain boundaries are formed so that current flows easily through the channel.

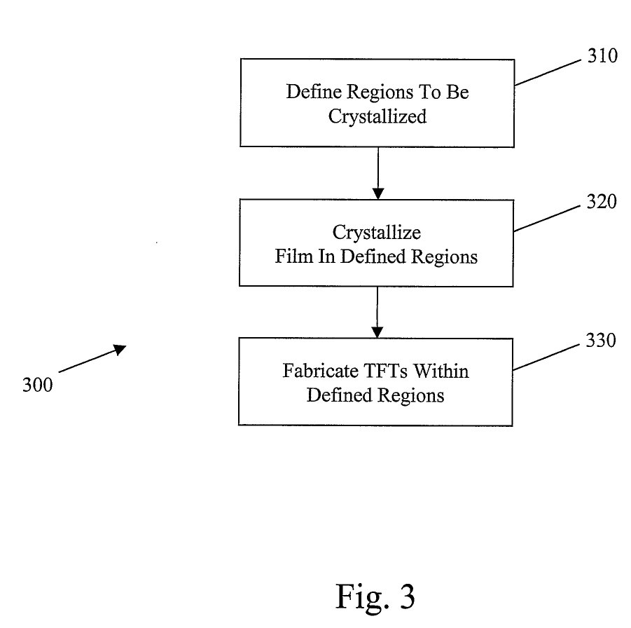

FIG. 3 shows a flow diagram of a method 300 for the high throughput crystallization of a semiconductor film, according to certain embodiments. First, the regions to be crystallized are defined (310). The defined regions may correspond to columns in which TFTs, e.g., pixel TFTs, will be fabricated. The column widths and spacings are selected according to the requirements of the device that will eventually be fabricated using the film.

Then, the film is crystallized in the defined regions (320) by processing the film with line-scan SLS to form elongated crystals, as described in greater detail below.

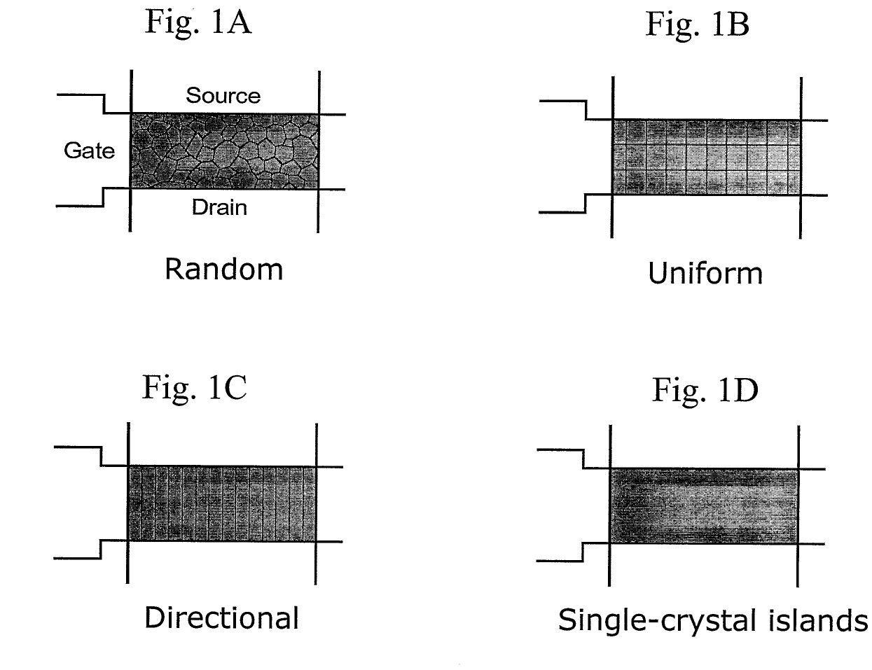

Then, TFTs are fabricated within the defined regions (330). This can be done with silicon island formation, in which the film is etched to remove excess silicon except where the TFTs are to be fabricated, for example, regions 230 of FIG. 2. Then, the remaining “islands” are processed using techniques known in the art to form active TFTs, including source and drain contact regions as illustrated in FIG. 1A.

Line-scan SLS addresses pulse non-uniformities that can arise in SLS systems and can detrimentally affect film uniformity and the performance of the finished device. Defects or variation in the quality of the semiconductor film affect TFT device quality, and controlling the nature and the location of these film defects or variations can reduce their impact on the resulting TFT devices.

In some embodiments, a line-scan SLS process uses a one dimensional (1D) projection system to generate a long, highly aspected laser beam, typically on the order of 1-100 cm in length, e.g., a “line beam.” The length to width aspect ratio may be in the range of about 50 or more, for example up to 100, or 500, or 1000, or 2000, or 10000, or up to about 2×10⁵, or more for example. In one or more embodiments, width is the average width of Wₘᵢₙ and Wₘₐₓ. The length of the beam at its trailing edges may not be well defined in some embodiments of line-scan SLS. For example, the energy may fluctuate and slowly drop off at the far ends of the length. The length of the line beam as referred to herein is the length of the line beam having a substantially uniform energy density, e.g., within 5% of the average energy density or fluence along the beam length. Alternatively, the length is the length of the line beam that is of sufficient energy density to perform the melt and solidification steps as described herein.

In line-scan SLS, the length of the highly aspected beam is preferably at least about the size of a single display, e.g., a liquid crystal or OLED display, or a multitude thereof or is preferably about the size of a substrate from which multiple displays can be produced. This is useful because it reduces or eliminates the appearance of any boundaries between irradiated regions of film. Any stitching artifacts that may arise when multiple scans across the film are needed, will generally not be visible within a given liquid crystal or OLED display. The beam length can be suitable for preparing substrates for cell phone displays, e.g., ˜2 inch diagonal for cell phones and ranging up to 10-16 inch diagonal for laptop displays (with aspect ratios of 2:3, 3:4 or other common ratios).

Crystallization with a long and narrow beam provides advantages when dealing with beams possessing inherent beam non-uniformities. For example, any non-uniformities along the long axis within a given laser pulse will be inherently gradual, and will be obscured over a distance much larger than the eye can detect. By making the long axis length larger, e.g., than the size of the fabricated liquid crystal or OLED display, abrupt changes at the edge of a laser scan may not be apparent within a given fabricated display.

Crystallization with a long and narrow beam will additionally reduce the effect of any non-uniformities in the short axis, because each individual TFT device in the display lies within an area that may be crystallized with at least a few pulses. In other words, the scale of non-uniformity along the short axis is on a scale smaller than that of a single TFT device and therefore will not cause variations in pixel brightness.

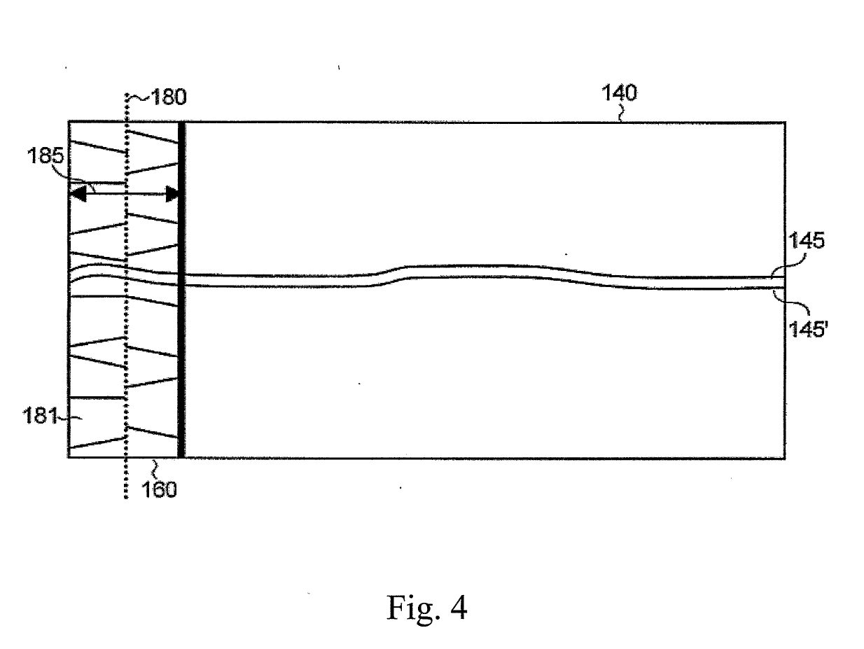

An exemplary method using a line beam for SLS processing of a thin film is described with reference to FIGS. 4-6. FIG. 4 shows a region 140 of a semiconductor film, e.g., an amorphous silicon film prior to “directional” crystallization, and an irradiating laser pulse in rectangular region 160. The laser pulse melts the film in region 160. The width of the melted region is referred to as the molten zone width (MZW). It should be noted that the laser irradiation region 160 is not drawn to scale in FIG. 4, and that the length of the region is much greater than the width, as is indicated by lines 145, 145′. This allows for a very long region of the film to be irradiated, for example, which is as long or longer than the length of a display that can be produced from the film. In some embodiments, the length of the laser irradiation region substantially spans several devices or even the width or length of the substrate. Using the appropriate laser source and optics, it is possible to generate a laser beam that is 1000 mm long, e.g., the dimension of a Gen 5 substrate, or even longer. In general, the width of the beam is sufficiently narrow that the fluence of laser irradiation is high enough to completely melt the irradiated region. In some embodiments, the width of the beam is sufficiently narrow to avoid nucleation in the crystals that subsequently grow in the melted region. The laser irradiation pattern, e.g., the image defined by the laser pulse, is spatially shaped using techniques described herein. For example, the pulse may be shaped by a mask or a slit. Alternatively, the pulse may be shaped using focusing optics.

After laser irradiation, the melted film begins to crystallize at the solid boundaries of region 160, and continues to crystallize inward towards centerline 180, forming crystals such as exemplary crystal 181. The distance the crystals grow, which is also referred to as the characteristic lateral growth length (characteristic “LGL”), is a function of the film composition, film thickness, the substrate temperature, the laser pulse characteristics, the buffer layer material, if any, and the mask configuration, etc., and can be defined as the LGL that occurs when growth is limited only by the occurrence of nucleation of solids in the supercooled liquid. For example, a typical characteristic lateral growth length for 50 nm thick silicon films is approximately 1-5 μm or about 2.5 μm. When growth is limited by other laterally growing fronts, as is the case here, where two fronts approach centerline 180, the LGL may be less than the characteristic LGL. In that case, the LGL is typically approximately one half the width of the molten zone.

The lateral crystallization results in “location-controlled growth” of grain boundaries and elongated crystals of a desired crystallographic orientation. Location-controlled growth referred to herein is defined as the controlled location of grains and grain boundaries using particular beam irradiation steps.

After the region 160 is irradiated and subsequently laterally crystallized, the silicon film can be advanced in the direction of crystal growth by a distance that is less than the lateral crystal growth length, e.g., not more than 90% of the lateral growth length. A subsequent laser pulse is then directed at a new area of the silicon film. For the fabrication of “directional” crystals, e.g., crystals having significant extension along a specific axis, the subsequent pulse preferably substantially overlaps with an area that has already been crystallized. By advancing the film a small distance, the crystals produced by earlier laser pulses act as seed crystals for subsequent crystallization of adjacent material. By repeating the process of advancing the film by small steps, and irradiating the film with a laser pulse at each step, crystals are made to grow laterally across the film, in the direction of the movement of the film relative to the laser pulse.

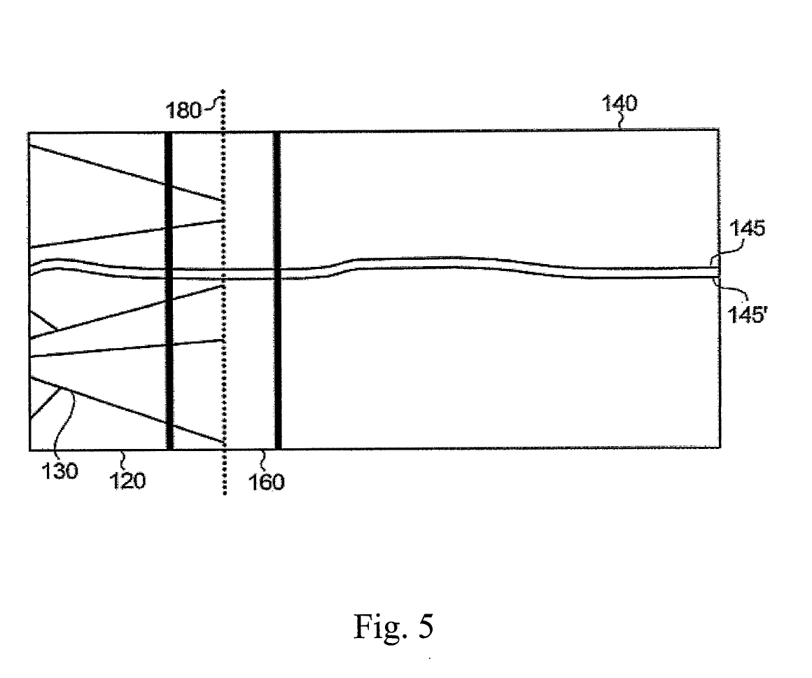

FIG. 5 shows the region 140 of the film after several iterations of moving the film and irradiating with laser pulses. As is clearly shown, an area 120 that has been irradiated by several pulses has formed elongated crystals that have grown in a direction substantially perpendicular to the length of the irradiation pattern. Substantially perpendicular means that a majority of lines formed by crystal boundaries 130 could be extended to intersect with dashed centerline 180.

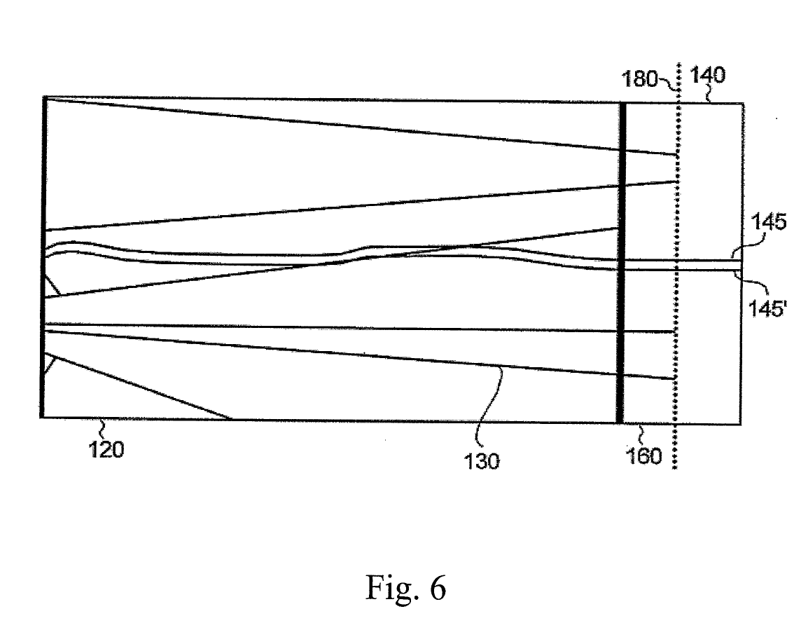

FIG. 6 shows the region 140 of film after crystallization is almost complete. The crystals have continued to grow in the direction of the movement of the film relative to the irradiation region thereby forming a polycrystalline region. The film preferably continues to advance relative to irradiated regions, e.g., region 160 by substantially equal distances. Iterations of moving and irradiating the film are continued until the irradiated area reaches the edge of a polycrystalline region of the film.

By using a number of laser pulses to irradiate a region, i.e., a small translation distance of the film between laser pulses, a film having highly elongated, low defect-density grains can be produced. Such a grain structure is referred to as “directional” because the grains are oriented in a clearly discernable direction. For further details, see U.S. Pat. No. 6,322,625, the contents of which are incorporated herein in their entirety by reference.

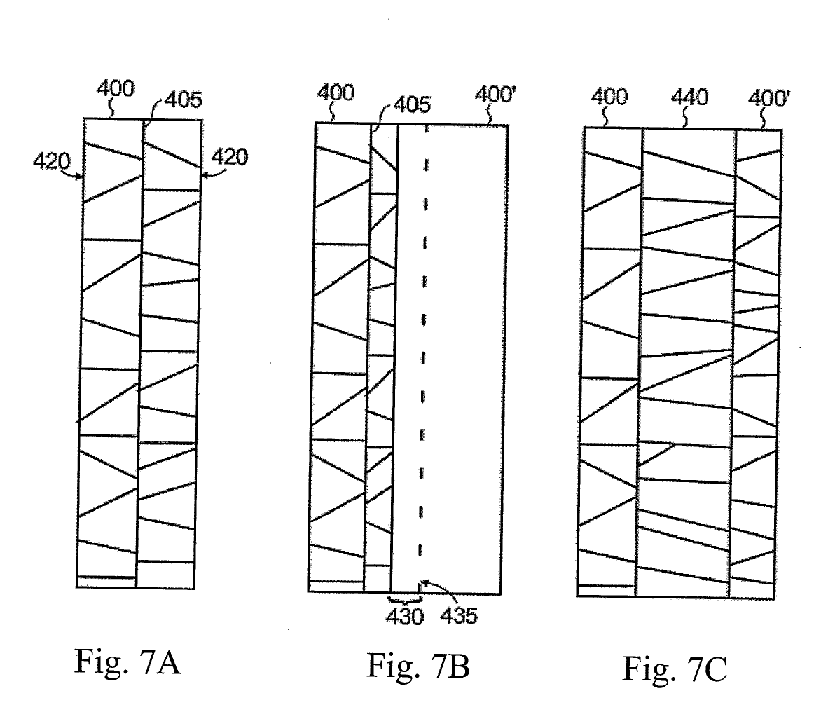

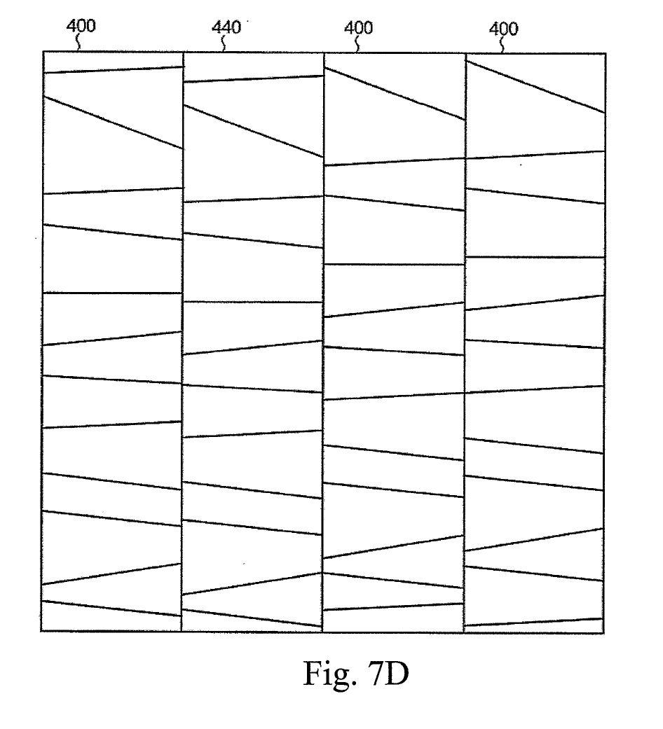

An alternative irradiation protocol, referred to herein as “uniform-grain sequential lateral solidification,” or “uniform SLS,” may be used to prepare a uniform crystalline film characterized by repeating columns of laterally elongated crystals. The crystallization protocol involves advancing the film by an amount greater than the lateral growth length, e.g., δ>LGL, where δ is the translation distance between pulses, and less than two times the lateral growth length, e.g., δ<2 LGL. Uniform crystal growth is described with reference to FIGS. 7A-7D.

Referring to FIG. 7A, a first irradiation is carried out on a film with a narrow, e.g., less than two times the lateral growth length, and elongated, e.g., greater than 10 mm and up to or greater than 1000 mm, laser beam pulse having an energy density sufficient to completely melt the film. As a result, the film exposed to the laser beam (shown as region 400 in FIG. 7A), is melted completely and then crystallized. In this case, grains grow laterally from an interface 420 between the unirradiated region and the melted region. By selecting the laser pulse width so that the molten zone width is less than about two times the characteristic LGL, the grains growing from both solid/melt interfaces collide with one another approximately at the center of the melted region, e.g., at centerline 405, and the lateral growth stops. The two melt fronts collide approximately at the centerline 405 before the temperature of the melt becomes sufficiently low to trigger nucleation.

Referring to FIG. 7B, after being displaced by a predetermined distance δ that is at least greater than about LGL and less than at most two LGL, a second region of the substrate 400′ is irradiated with a second laser beam pulse. The displacement of the substrate, δ, is related to the desired degree of overlap of the laser beam pulse. As the displacement of the substrate becomes longer, the degree of overlap becomes less. It is advantageous and preferable to have the overlap degree of the laser beam to be less than about 90% and more than about 10% of the LGL. The overlap region is illustrated by brackets 430 and dashed line 435. The film region 400′ exposed to the second laser beam irradiation melts completely and crystallizes. In this case, the grains grown by the first irradiation pulse serve as crystallizing seeds for the lateral growth of the grains grown from the second irradiation pulse. FIG. 7C illustrates a region 440 having crystals that are laterally extended beyond a lateral growth length. Thus, a column of elongated crystals are formed by two laser beam irradiations on average. Because two irradiation pulses are all that is required to form the column of laterally extended crystals, the process is also referred to as a “two shot” process. Irradiation continues across the substrate to create multiple columns of laterally extended crystals. FIG. 7D illustrates the microstructure of the substrate after multiple irradiations and depicts several columns 440 of laterally extended crystals.

Thus, in uniform SLS, a film is irradiated and melted with a low number of pulses, e.g., two, which laterally overlap to a more limited extent than for a “directional” film. The crystals that form within the melted regions preferably grow laterally and with a similar orientation, and meet each other at a boundary within the particular irradiated region of film. The width of the irradiation pattern is preferably selected so that the crystals grow without nucleation. In such instances, the grains are not significantly elongated; however, they are of uniform size and orientation. For further details, see U.S. Pat. No. 6,573,531, the contents of which are incorporated herein in their entirety by reference.

Conventional line-scan SLS systems typically have a relatively low throughput because the beam is narrowly focused. For example, a 4 kHz 600 W laser in a system creating a 1 m×6 μm size laser line beam with an optical efficiency of 30% has to a 750 mJ/cm² energy density. The resultant line beam can crystallize a film at a rate of 0.4-0.8 cm/s, when stepping 1-2 μm to create a “directional” crystalline silicon film, and 1.6-2.0 cm/s when stepping at 4-5 μm to create a “uniform” crystalline silicon film.

The high throughput systems and methods described herein provide scan velocities that are at least a factor of ten greater than those typically achievable with conventional line-scan SLS without sacrificing crystalline quality in the regions where it is needed. In certain embodiments, a line-scan process is used to selectively crystallize defined regions of the substrate, e.g., those regions where TFTs are optionally fabricated, and the other regions of the substrate are left untreated and may be, e.g., amorphous or polycrystalline, as described in greater detail herein. These embodiments can increase the “effective” scan rate, e.g., the overall scan rate including the rate of crystallizing the defined regions and the rate of scanning the film to skip the untreated regions, to exemplary rates of 6 cm/s or more. Note that the crystallized region may be selected for only a portion of the TFT, for example, the integration regions or the pixel regions of the TFT. Alternatively, the crystallized regions may be selected to accommodate any other type of device or feature.

In some embodiments, the width of the crystallized regions is at least wide enough to cover the area from source to drain of the TFT to be optionally fabricated, including part of the highly doped source and drain contacts. In other embodiments, the width of the crystallized regions is sufficient to prepare pixel and integration TFTs. The TFT is then fabricated so that its shortest dimension (the channel length) is oriented parallel to the parallel grain boundaries formed by the SLS process, e.g., as illustrated in FIG. 1C. This way, current will flow readily through the TFT channel from source to drain, and not be disrupted by the presence of grain boundaries.

In some embodiments, the process employs a high frequency, high power pulsed laser source. The high power laser provides sufficient energy per pulse to provide adequate energy density across the length of an irradiated region that the pulse may melt a film within that region. The higher frequency permits a film to be scanned or translated relative to the irradiated region at a rate that can be used in commercially practical applications. In one or more embodiments, the laser source is capable of a pulse frequency of greater than about 1 kHz, or up to about 9 kHz. In other embodiments, the laser source is capable of a pulse frequency of up to 100 kHz or more, which is a range made possible by pulsed solid-state lasers. However, the embodiments are not limited to lasers of any particular frequencies. For example, low frequency lasers, e.g., less than 1 kHz, are also compatible with the irradiation schemes described herein.

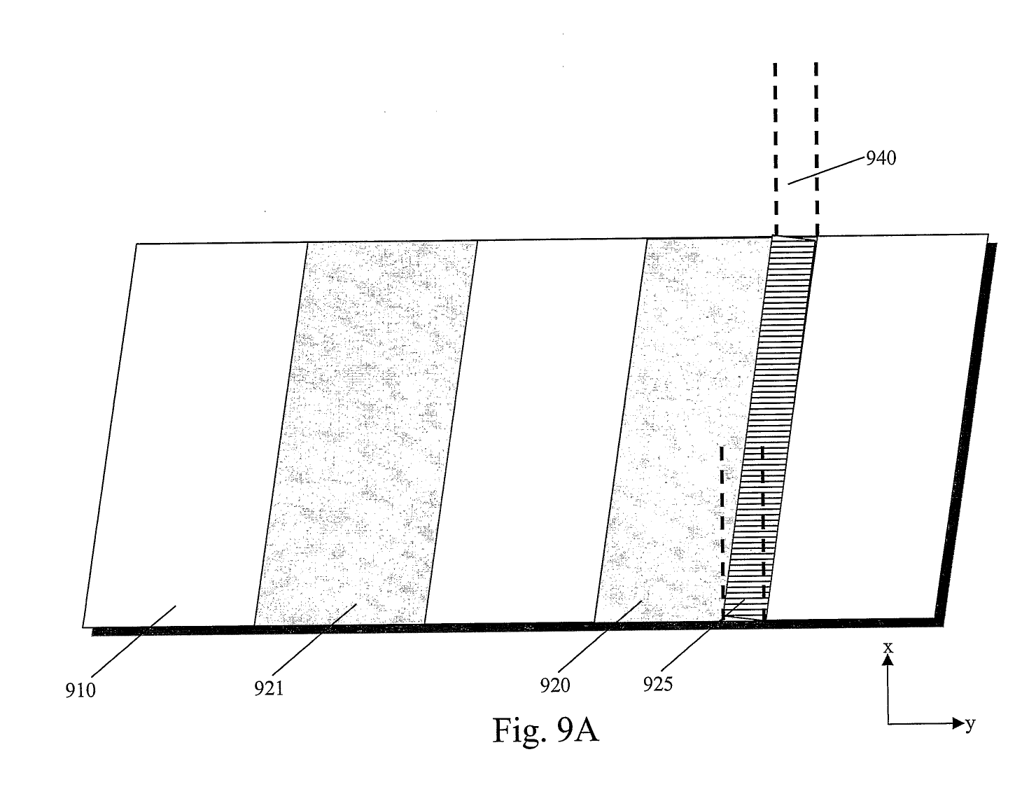

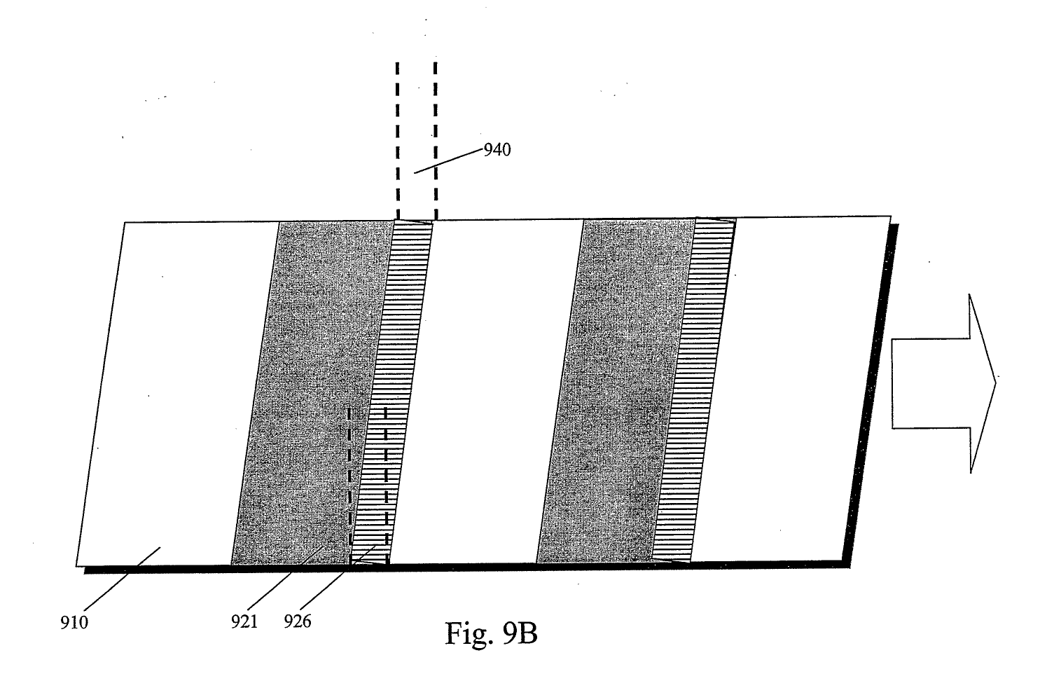

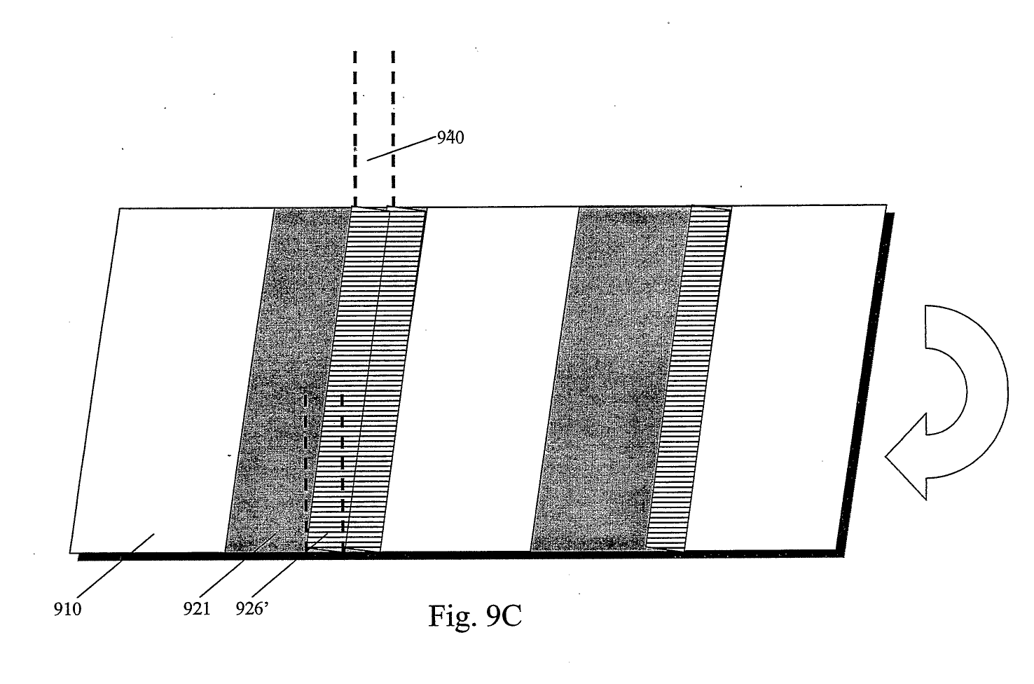

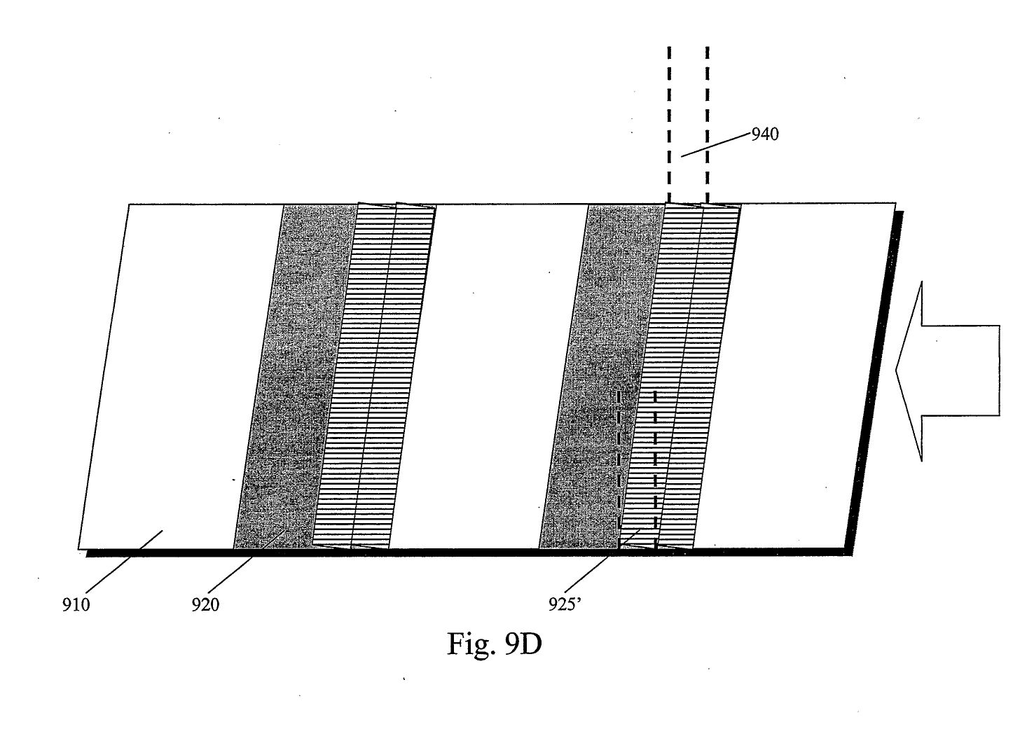

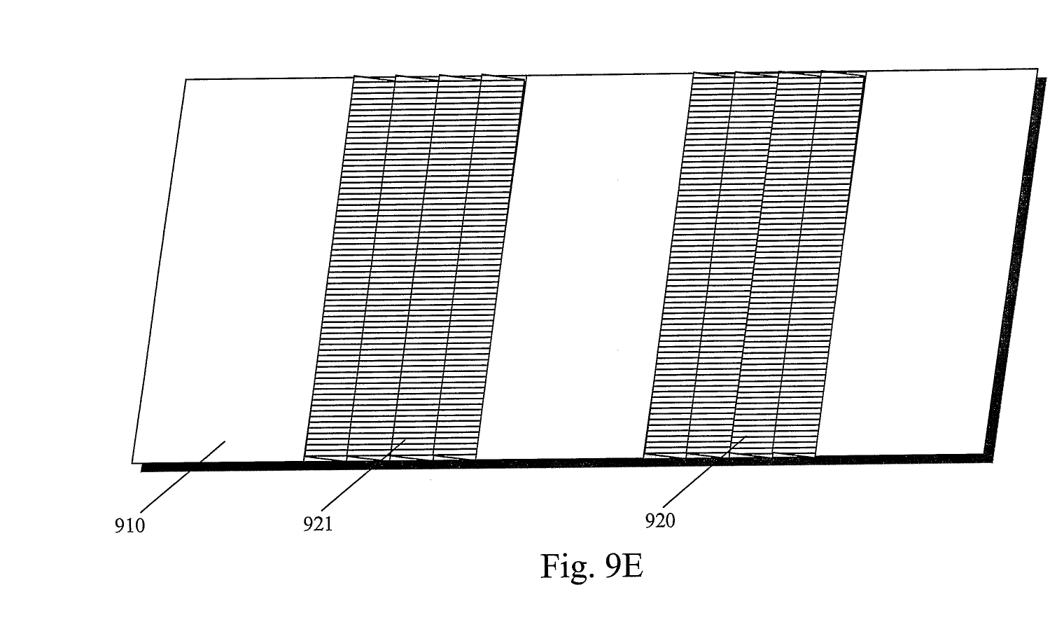

FIGS. 9A-9E show different steps in an exemplary method for high-throughput directional crystallization of a substrate 910. In one step, as shown in FIG. 9A, laser beam 940 (the general profile of which is indicated by dashed lines) irradiates and melts a portion 925 of a first defined region 920 of the film. The irradiated portion 925 recrystallizes upon cooling to form a laterally crystallized portion of first defined region 920 as illustrated in FIG. 9B.

Subsequently, as shown in FIG. 9B, the stage (not shown) on which substrate 910 is mounted moves in the (+y) direction, so that the laser beam 940 next irradiates a portion 926 of a second defined region 921 of the film. The laser beam melts portion 926, which recrystallizes upon cooling to form a laterally crystallized portion of second defined region 921. FIG. 9B illustrates the resultant elongated crystals of portion 926.

Subsequently, the stage passes the end of the substrate, decelerates, reverses direction, and begins moving in the (−y) direction, so that laser beam 940 next irradiates and melts a portion 926′ of defined region 921 that overlaps a portion of the previously crystallized region 926, as shown in FIG. 9C.

Although FIG. 9C shows portions 926 and 926′ as having minimal overlap, in general the amount of overlap between the portions can be selected to provide a particular microstructure to the crystallized film. For example, the method can be used to create “directional” and/or “uniform” films, as described above, and as described in greater detail in U.S. patent application Ser. No. 11/293,655. For example, in some embodiments the overlap has a length that is less than the lateral growth length of the crystals. This yields a large amount of overlap between portions 926 and 926,′ which allows the crystals produced in portion 926 to act as seed crystals for the crystals subsequently produced in region 926′. This produces “directional” crystals, e.g., crystals having significant extension along the axis parallel to the scan direction. Or, for example, in some embodiments the overlap length film is greater than the lateral growth length of the crystals, and less than two times the lateral growth length. Here, crystals in portion 926 act as seed crystals for the crystals grown in region 926′, but the overlap between successive portions is low, so that as the scan progresses any given portion of region 921 will have only been irradiated with a low number of pulses, e.g., 2. This forms “uniform” crystals. The desired properties of the finished device determine which kind of crystal microstructure should be produced, i.e., how much overlap should be made between successive portions of film within a defined region.

Subsequently, as shown in FIG. 9D, the stage continues to move in the (−y) direction, so that the laser beam 940 next irradiates another portion 925′ of first defined region 920. As discussed above, the amount of overlap between the portions 925 and 925′ is selected to provide the desired microstructure to the film.

Continuing these steps, the remaining portions of defined regions 920 and 921 are crystallized, as illustrated in FIG. 9E. Although only two defined regions are illustrated, it should be understood that a plurality of regions across the surface of the film 910 can be crystallized in this way.

Because the distance between laser pulses far exceeds the lateral growth length of the thin film material, the scan speed of the film is significantly increased. Because the entire surface of the thin film need not be irradiated, the number of line beam pulses needed to complete the irradiation process is significantly reduced. This reduces processing time and increases productivity without sacrificing crystalline quality.

In the embodiment illustrated in FIG. 9A-9E, the stage moves continuously at a relatively high velocity, and the laser is triggered to provide laser pulses at specific times so that those pulses irradiate the correct region of the film, as the different regions pass under the laser beam. The stage velocity v is related to the spacing P between the regions to be crystallized, also called the scan pitch, and the frequency f of the laser, by:

ν_{stage}=P·f

The effective velocity ν_{eff} of the scan is related to the stage velocity ν_{stage}, and is also related to the number of pulses n needed to crystallize each region by:

ν_{eff}=ν_{stage}/n

So, for example, assuming the regions to be crystallized are 20 μm wide columns spaced 200 μm apart, and further assuming the laser operates at 4 kHz, and that 10 pulses are needed to crystallize a column, ν_{stage}=60 cm/s and ν_{eff}=6 cm/s. Note that the effective velocity ν_{eff} of the scan may be reduced further by the amount of time that it takes the stage to reverse direction at the end of each pass of the film, and the number of times (n−1) that the stage must reverse directions. Even given this additional delay, conventional line-scan SLS systems and methods are relatively slower, and thus have lower throughput. For example, assuming the same parameters as given for the high throughput system, and further assuming a step size of 1 μm-5 μm, the scan velocity for line-scan SLS across the film is 0.4-1.8 cm/s. Thus, processing speed can be dramatically increased by crystallizing the film in regions where crystal orientation will substantially affect the performance of the device, as compared to that achievable in typical line-scan SLS.

Any acceleration or deceleration of the stage takes time, so in many embodiments, the stage velocity is held substantially constant on a given scan of the line beam across the film. In order to achieve this constant velocity, in some embodiments after a first scan in the (+y) direction of the film, the stage “overshoots” the film, decelerates, reverses direction where the film is not irradiated by the beam, accelerates, and then moves the film under the beam at a constant velocity in the (−y) direction.

In certain embodiments, a single pulse is sufficient to crystallize a TFT region, in which case the method would be more properly referred to as controlled super-lateral growth, or “C-SLG.”

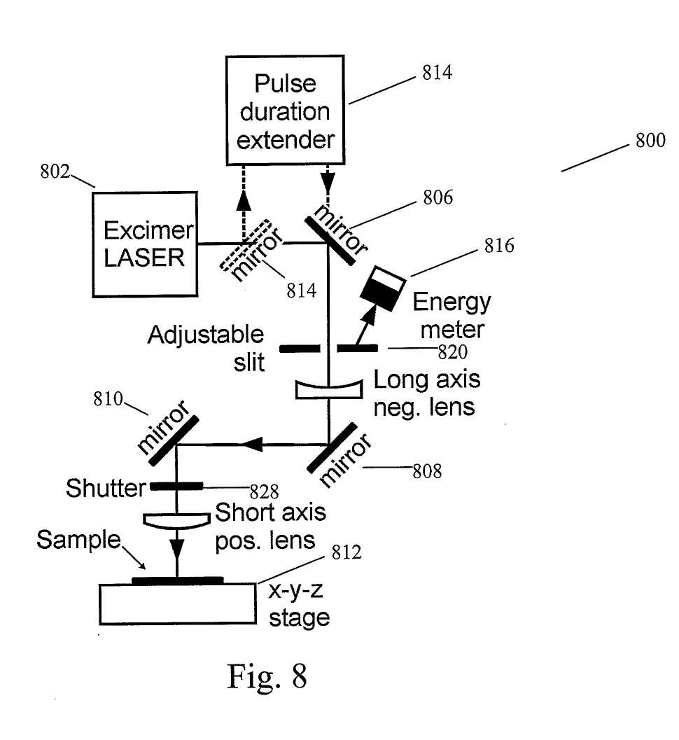

A schematic illustration of a line scan crystallization system 800 using high aspect ratio pulses is shown in FIG. 8. The system includes a laser pulse source 802, operating for instance at 308 nm (XeCl) or 248 nm or 351 nm. A series of mirrors 806, 808, 810 direct the laser beam to a sample stage 812, which is capable of sub-micron precision in the x-, and z- (and optionally y-) directions. The system also includes slit 820 that may be used to control the spatial profile of the laser beam and energy density meter 816 to read the reflection of slit 820. Shutter 828 can be used to block the beam when no sample is present or no irradiation is desired. Sample 830 may be positioned on stage 812 for processing.

Laser-induced crystallization is typically accomplished by laser irradiation using a wavelength of energy that can be at least partially absorbed by the film, with an energy density, or fluence, high enough to melt the film. Although the film can be made of any material susceptible to melt and recrystallization, silicon is a preferred material for display applications.

In one embodiment, the laser pulses generated by the source 802 have an energy in the range of 50-200 mJ/pulse and a pulse repetition rate around 4000 Hz or more. Excimer lasers currently available from Cymer, Inc. San Diego, Calif., can achieve this output. Although an excimer laser system is described, it is appreciated that other sources capable of providing laser pulses at least partially absorbable by a desired film may be used. For example, the laser source may be any conventional laser source, including but not limited to, excimer laser, continuous wave laser and solid-state laser. The irradiation beam pulse can be generated by another known source or short energy pulses suitable for melting a semiconductor can be used. Such known sources can be a pulsed solid state laser, a chopped continuous wave laser, a pulsed electron beam and a pulsed ion beam, etc.

The system optionally includes a pulse duration extender 814 that is used to control the temporal profile of the laser pulses. Optional mirror 804 can be used to direct the laser beam into extender 814, in which case mirror 806 would be removed. Since crystal growth can be a function of the duration of the laser pulse used to irradiate the film, pulse duration extender 814 can be used to lengthen the duration of each laser pulse to achieve a desired pulse duration. Methods of extending pulse durations are known.

Slit 820 can be used to control the spatial profile of the laser beam. Specifically, it is used to give the beam a high aspect ratio profile. The laser beam from source 802 may have a Gaussian profile, for example. Slit 820 significantly narrows one spatial dimension of the beam. For example, before slit 820, the beam may be between 10 and 15 mm wide and 10 to 30 mm long. The slit could be substantially thinner than the width, for example about 300 microns wide, which results in a laser pulse that has a short axis of about 300 microns, and a long axis that may be unmodified by the slit. Slit 820 is a simple method of producing a narrow beam from a relatively wide beam, and also has the benefit of providing a ‘top hat’ spatial profile, which has a relatively uniform energy density across the short axis. In another embodiment, instead of using slit 820, a very short focal length lens can be used to tightly focus one dimension of a laser beam onto the silicon film. It is also possible to focus the beam onto the slit 820; or, more generally, using optical elements (e.g., a simple cylindrical lens) to narrow the short axis of the beam from source 802 so that less energy is lost upon passing slit 820 yet some sharpening is achieved.

The laser beam is then modified using two fused silica cylindrical lenses 820, 822. The first lens 820, which is a negative focal length lens, expands the size of the long axis of the beam, the profile of which may be relatively uniform, or may have gradual changes that are not apparent over the length of the long axis. The second lens 822 is a positive focal length lens that reduces the size of the short axis. The projection optics reduce the size of the laser beam in at least the short dimension, which increases the fluence of the laser pulse when it irradiates the film. The projection optics may be a multiple-optic system that reduces the size of the laser beam in at least the short dimension by a factor of 10-30×, for example. The projection optics may also be used to correct for spatial aberrations in the laser pulses, for example, spherical aberrations. In general, the combination of slit 820, lenses 820, 822, and the projection optics is used to ensure that each laser pulse irradiates the film with an energy density that is high enough to melt the film, with a homogeneity and length along the long axis that is sufficiently long to minimize or eliminate variations of the crystallization of the film. Thus, for example, a 300 micron wide beam is reduced to, for example, a 10 micron width. Narrower widths are also contemplated. Homogenizers may also be used on the short axis.

In some embodiments, the line scan crystallization system 800 can include a variable attenuator and/or a homogenizer, which can be used to improve the spatial homogeneity along the long axis of the laser beam. The variable attenuator can have a dynamic range capable of adjusting the energy density of the generated laser beam pulses. The homogenizer can consist of one or two pairs of lens arrays (two lens arrays for each beam axis) that are capable of generating a laser beam pulses that have uniform energy density profiles.

In general, the film itself is not required to move during crystallization; the laser beam or a mask defining the laser beam shape could be scanned across the film instead to provide a relative motion of the irradiated region and the film. However, moving the film relative to the laser beam may provide improved uniformity of the laser beam during each subsequent irradiation event.

The line scan crystallization system may be configured to create a long and narrow laser beam that measures, for example, about 4-15 μm on the short axis and can be 50-100 microns on the long axis in some embodiments, and tens of centimeters or up to more than one meter on the long axis in other embodiments. In general the aspect ratio of the beam is high enough that the irradiated region can be considered a “line.” The length to width aspect ratio may be in the range of about 50 up to about 1×10⁵ or more, for example. In one or more embodiments, the width of the short axis does not exceed the width of twice the characteristic lateral growth length of the laterally solidified crystals, so that no nucleated polysilicon is formed between the two laterally grown areas. This is useful for the growth of “uniform” crystals and also for the general improvement of crystal quality. The desired length of the long axis of the laser beam may be dictated by the size of the substrate, and the long axis may extend substantially along the entire length of the substrate, or of the display to be fabricated (or a multitude thereof), or of a single TFT device in the display, or a TFT circuit on the periphery of the display (e.g., containing drivers) or in other words the integration area. The beam length can in fact also be dictated by the dimension of the integration areas of two adjacent displays combined. The energy density, or fluence, uniformity along the length of the beam is preferably uniform and for example varies by no more than 5% along its entire length. In other embodiments, the energy density along the length of the beam covering the length of interest is of a sufficiently low value that no agglomeration occurs in either one or as a result of a series of overlapping pulses. Agglomeration is a result of localized high energy density that can lead to film disruption.

Further details of line-scan SLS may be found in U.S. patent application Ser. No. 11/293,655, filed Dec. 2, 2005 and entitled “Line Scan Sequential Lateral Solidification of Thin Films,” the entire contents of which are incorporated herein by reference.

Other embodiments are within the following claims.

What is claimed is:

1. A method of processing a film, the method comprising:
(a) defining a plurality of spaced-apart regions to be crystallized within a film, said film being disposed on a substrate and capable of laser-induced melting;
(b) generating a sequence of laser pulses having a fluence that is sufficient to melt the film throughout its thickness in an irradiated region, each pulse forming a line beam having a length and a width;
(c) continuously scanning the film in a first scan with a sequence of laser pulses at a velocity selected such that each pulse irradiates and melts a first portion of a corresponding spaced-apart region, wherein the first portion upon cooling forms one or more laterally grown crystals; and
(d) continuously scanning the film in a second time with a sequence of laser pulses at a velocity selected such that each pulse irradiates and melts a second portion of a corresponding spaced-apart region, wherein the first and second portions in each spaced-apart region partially overlap, and wherein the second portion upon cooling forms one or more laterally grown crystals that are extended relative to the one or more laterally grown crystals of the first portion.

2. The method of claim 1, further comprising reversing the scan direction between the first and second scans.

3. The method of claim 1, further comprising continuously scanning the film relative to the sequence of laser pulses a plurality of times, and on each scan irradiating a portion of each spaced-apart region that partially overlaps with a previously irradiated portion of that region.

4. The method of claim 3, further comprising reversing the scan direction between each scan.

5. The method of claim 1, further comprising fabricating at least one thin film transistor in at least one spaced-apart region.

6. The method of claim 1, further comprising fabricating a plurality of thin film transistors in a plurality of spaced-apart regions.

7. The method of claim 1, wherein defining a plurality of spaced-apart regions comprises defining a width for each spaced-apart region that is at least as large as a device intended to be later fabricated in that region.

8. The method of claim 1, wherein defining a plurality of spaced-apart regions comprises defining a width for each spaced-apart region that is at least as large as a width of a thin film transistor intended to be later fabricated in that region.

9. The method of claim 1, comprising overlapping the first and second portions of each spaced-apart region by an amount that is less than a lateral growth length of the one or more laterally grown crystals of the first portion.

10. The method of claim 1, comprising overlapping the first and second portions of each spaced-apart region by an amount that is not more than 90% of the lateral growth length of the one or more laterally grown crystals of the first portion.

11. The method of claim 1, comprising overlapping the first and second portions of each spaced-apart region by an amount that is greater than a lateral growth length and less than about twice the lateral growth length of the one or more laterally grown crystals of the first portion.

12. The method of claim 1, comprising overlapping the first and second portions of each spaced-apart region by an amount that is more than 110% and less than about 190% of a lateral growth length of the one or more laterally grown crystals of the first portion.

13. The method of claim 1, comprising overlapping the first and second portions of each spaced-apart region by an amount selected to provide a set of predetermined crystalline properties to the spaced-apart region.

14. The method of claim 13, wherein the set of predetermined crystalline properties are suitable for a channel region of a pixel TFT.

15. The method of claim 1, wherein the spaced-apart regions are separated by amorphous film.

16. The method of claim 1, wherein the spaced-apart regions are separated by polycrystalline film.

17. The method of claim 1, wherein the line beam has a length to width aspect ratio of at least 50.

18. The method of claim 1, wherein the line beam has a length to width aspect ratio of up to 2×10⁵.

19. The method of claim 1, wherein the length of the line beam is at least as large as one-half a length of the substrate.

20. The method of claim 1, wherein the length of the line beam is at least as large as a length of the substrate.

21. The method of claim 1, wherein the length of the line beam is between about 10 cm and 100 cm.

22. The method of claim 1, comprising shaping each pulse of the sequence of pulses into a line beam using one of a mask, a slit, and a straight edge.

23. The method of claim 1, comprising shaping each pulse of the sequence of pulses into a line beam using focusing optics.

24. The method of claim 1, wherein the fluence of the line beam varies by less than about 5% along its length.

25. The method of claim 1, wherein the film comprises silicon.

26. A method of processing a film, the method comprising:
(a) defining at least first and second regions to be crystallized within a film;
(b) generating a sequence of laser pulses having a fluence that is sufficient to melt the film throughout its thickness in an irradiated region, each pulse forming a line beam having a length and width;
(c) irradiating and melting a first portion of the first region with a first laser pulse of the sequence of pulses, said first portion of the first region upon cooling forming one or more laterally grown crystals;
(d) irradiating and melting a first portion of the second region with a second laser pulse of the sequence of pulses, said first portion of the second region upon cooling forming one or more laterally grown crystals;
(e) irradiating and melting a second portion of the second region of the plurality of regions with a third laser pulse of the sequence of pulses, said second portion of the second region overlapping with the first portion of the second region and upon cooling forming one or more laterally grown crystals; and
(f) irradiating and melting a second portion of the first region of the plurality of regions with a fourth laser pulse of the sequence of pulses, said second portion of the first region overlapping with the first portion of the first region and upon cooling forming one or more laterally grown crystals.

27. The method of claim 26, wherein the one or more laterally grown crystals in the second portion of the first defined region are elongations of the one or more laterally grown crystals in the first portion of the first defined region.

28. The method of claim 26, further comprising fabricating at least one thin film transistor in at least one of the first and second regions.

29. The method of claim 26, further comprising defining a width for each of the first and second regions that is at least as large as a device intended to be later fabricated in that region.

30. The method of claim 26, further comprising defining a width for each of the first and second regions that is at least as large as a width of a thin film transistor intended to be later fabricated in that region.

31. The method of claim 26, comprising overlapping the first and second portions of each of the first and second regions by an amount that is less than a lateral growth length of the one or more crystals of the first portions.

32. The method of claim 26, comprising overlapping the first and second portions of each of the first and second regions by an amount that is not more than 90% of a lateral growth length of the one or more crystals of the first portions.

33. The method of claim 26, comprising overlapping the first and second portions of each of the first and second regions by an amount that is greater than a lateral growth length and less than about twice the lateral growth length of the one or more crystals of the first portions.

34. The method of claim 26, comprising overlapping the first and second portions of each of the first and second regions by an amount that is more than about 110% and less than about 190% of the lateral growth length of the one or more crystals of the first portions.

35. The method of claim 26, comprising overlapping the first and second portions of each of the first and second regions by an amount selected to provide a set of predetermined crystalline properties to each of the first and second regions.

36. The method of claim 35, wherein the set of predetermined crystalline properties are suitable for a channel region of a pixel TFT.

37. The method of claim 26, comprising executing steps (a)-(f) in that order.

38. The method of claim 26, wherein the first and second regions are separated by uncrystallized film.

39. The method of claim 26, wherein the first and second regions are separated by polycrystalline film.

40. The method of claim 26, further comprising moving the film relative to the line beam.

41. The method of claim 26, further comprising scanning the film in one direction relative to the line beam while irradiating the first portions of the first and second regions, and scanning the film in an opposite direction relative to the line beam while irradiating the second portions of the first and second regions.

42. The method of claim 26, wherein the line beam has a length to width aspect ratio of at least 50.

43. The method of claim 26, wherein the line beam has a length to width aspect ratio of up to 2×10⁵.

44. The method of claim 26, wherein the length of the line beam is at least as large as one-half a length of the substrate.

45. The method of claim 26, wherein the length of the line beam is at least as large as the length of the substrate.

46. The method of claim 26, wherein the length of the line beam is between about 10 cm and 100 cm.

47. The method of claim 26, comprising shaping each pulse of the sequence of pulses into a line beam using one of a mask, a slit, and a straight edge.

48. The method of claim 26, comprising shaping each pulse of the sequence of pulses into a line beam using focusing optics.

49. The method of claim 26, wherein the line beam has a fluence that varies by less than about 5% along its length.

50. The method of claim 26, wherein the film comprises silicon.

51. A system for processing a film, the system comprising:
a laser source providing a sequence of laser pulses;
laser optics that shape the laser beam into a line beam, the line beam having a fluence that is sufficient to melt a film throughout its thickness in an irradiated region, the line beam further having a length and a width;
a stage for supporting the film and capable of translation in at least one direction;
memory for storing a set of instructions, the instructions comprising:
(a) defining a plurality of spaced-apart regions to be crystallized within the film;
(b) continuously translating the film on the stage a first time relative to the sequence of laser pulses at a velocity selected such that each pulse irradiates and melts a first portion of a corresponding spaced-apart region, wherein the first portion upon cooling forms one or more laterally grown crystals; and
(c) continuously translating the film on the stage a second time relative to the sequence of laser pulses at a velocity selected such that each pulse irradiates and melts a second portion of a corresponding spaced-apart region, wherein the first and second portions in each spaced-apart region partially overlap, and wherein the second portion upon cooling forms one or more laterally grown crystals.

52. The system of claim 51, wherein the memory further includes instructions to reverse the scan direction between the first and second scans.

53. The system of claim 51, wherein the memory further includes instructions to continuously translate the stage relative to the sequence of laser pulses a plurality of times, and on each scan irradiating a portion of each spaced-apart region that partially overlaps with a previously irradiated portion of that region.

54. The system of claim 53, wherein the memory further includes instructions to reverse the scan direction between each scan.

55. The system of claim 51, wherein the memory further includes instructions for defining defining a width for each spaced-apart region that is at least as large as a device intended to be later fabricated in that region.

56. The system of claim 51, wherein the memory further includes instructions for defining a width for each spaced-apart region that is at least as large as a width of a thin film transistor intended to be later fabricated in that region.

57. The system of claim 51, wherein the memory further includes instructions for overlapping the first and second portions of each spaced-apart region by an amount that is less than a lateral growth length of the one or more laterally grown crystals of the first portion.

58. The system of claim 51, wherein the memory further includes instructions for overlapping the first and second portions of each spaced-apart region by an amount that is not more than 90% of the lateral growth length of the one or more laterally grown crystals of the first portion.

59. The system of claim 51, wherein the memory further includes instructions for overlapping the first and second portions of each spaced-apart region by an amount that is greater than a lateral growth length and less than about twice the lateral growth length of the one or more laterally grown crystals of the first portion.

60. The system of claim 51, wherein the memory further includes instructions for overlapping the first and second portions of each spaced-apart region by an amount that is more than about 110% and less than about 190% of a lateral growth length of the one or more laterally grown crystals of the first portion.

61. The system of claim 51, wherein the memory further includes instructions for overlapping the first and second portions of each spaced-apart region by an amount selected to provide a set of predetermined crystalline properties to the spaced-apart region.

62. The system of claim 61, wherein the set of predetermined crystalline properties are suitable for a channel region of a pixel TFT.

63. The system of claim 51, wherein the laser optics shape the line beam to have a length to width aspect ratio of at least 50.

64. The system of claim 51, wherein the laser optics shape the line beam to have a length to width aspect ratio of up to 2×10⁵.

65. The system of claim 51, wherein the laser optics shape the line beam to be at least as large as one-half a length of the film.

66. The system of claim 51, wherein the laser optics shape the line beam to be at least as large as a length of the film.

67. The system of claim 51, wherein the laser optics shape the line beam to have a length between about 10 cm and 100 cm.

68. The system of claim 51, wherein the laser optics include at least one of a mask, a slit, and a straight edge.

69. The system of claim 51, wherein the laser optics include focusing optics.

70. The system of claim 51, wherein the laser optics shape the line beam to have a fluence that varies by less than about 5% along its length.

71. The system of claim 51, wherein the film comprises silicon.

72. A thin film, comprising:
columns of crystallized film positioned and sized so that rows and columns of TFTs can later be fabricated in said columns of crystallized film and having as set of predetermined crystalline qualities suitable for a channel region of a TFT; and
columns of untreated film between said columns of crystallized film.

73. The film of claim 72, wherein the columns of untreated film comprise amorphous film.

74. The film of claim 72, wherein the columns of untreated film comprise polycrystalline film.
